(19) United States
(12) Patent Application Publication
(10) Pub. No.: US 2026/0194782 A1
(43) Pub. Date: Jul. 9, 2026

(54) ELECTROCHROMIC COMPOSITION, MULTILAYERED STRUCTURE, AND ELECTROCHROMIC DEVICE

(71) Applicant: INDUSTRIAL TECHNOLOGY RESEARCH INSTITUTE, Hsinchu (TW)

(72) Inventors: Hsiang-Jui CHEN, Hsinchu City (TW); Jheng-Ying LI, Taoyuan City (TW); Jauder JENG, Zhudong Township (TW)

(73) Assignee: INDUSTRIAL TECHNOLOGY RESEARCH INSTITUTE, Hsinchu (TW)

(21) Appl. No.: 19/073,217

(22) Filed: Mar. 7, 2025

(30) Foreign Application Priority Data
Jan. 6, 2025 (TW) 114100453

(51) Int. Cl. G02F 1/1516

(52) U.S. Cl. CPC G02F 1/15165

(57) ABSTRACT

An electrochromic composition includes 100 parts by weight of polyimide, 0.0001 to 0.01 parts by weight of crosslinking agent, 5 to 50 parts by weight of electrochromic material, and 150 to 350 parts by weight of solvent. The polyimide is formed by reacting dianhydride monomers and diamine monomers. The dianhydride monomers are selected from at least two members of a group consisting of several types of dianhydride monomers. The diamine monomers are a combination of

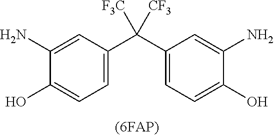 [SMILES: Nc1cc(C(c2ccc(O)c(N)c2)(C(F)(F)F)C(F)(F)F)ccc1O]

and another diamine monomer, and 6FAP accounts for 15 mol % to 55 mol % of the diamine monomers.

### CROSS REFERENCE TO RELATED APPLICATIONS

The present application is based on, and claims priority from, Taiwan Application Serial Number 114100453, filed on Jan. 6, 2025, the disclosure of which is hereby incorporated by reference herein in its entirety.

### TECHNICAL FIELD

The technical field relates to an electrochromic film, and in particular it relates to an electrochromic composition for forming an electrochromic film.

### BACKGROUND

Electrochromic technology offers numerous advantages, such as high transparency, low energy consumption, and the like. As a result, electrochromic technology can be widely used in various industries such as architecture, automobiles, aircraft, and ships. Electrochromic technology can maximize natural light and outdoor views, improve livability, reduce energy costs, and provide high aesthetic value. In view of its overall applications, element sizes are gradually increasing, and there is a growing trend towards using lightweight, flexible substrates in optoelectronic applications.

### SUMMARY

One embodiment of the disclosure provides an electrochromic composition, including 100 parts by weight of polyimide, 0.0001 to 0.01 parts by weight of crosslinking agent, 5 to 50 parts by weight of electrochromic material, and 150 to 350 parts by weight of solvent. The polyimide is formed by reacting dianhydride monomers and diamine monomers. The dianhydride monomers are selected from at least two members of a group consisting of

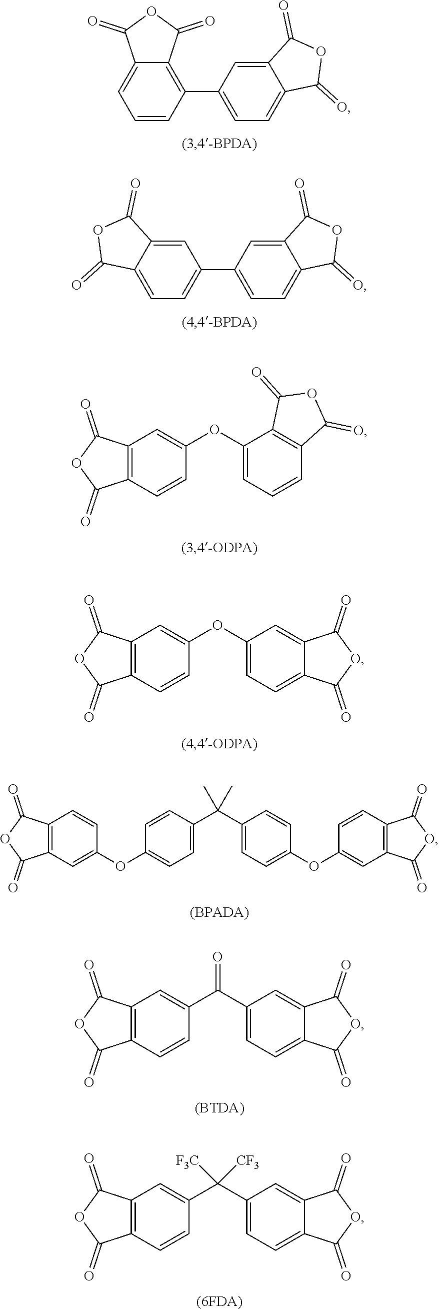

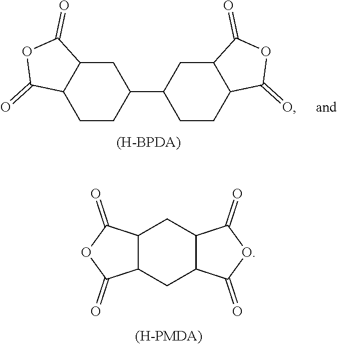

The diamine monomers are a combination of

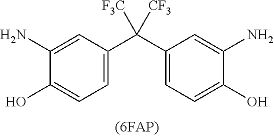 [SMILES: Nc1cc(C(c2ccc(O)c(N)c2)(C(F)(F)F)C(F)(F)F)ccc1O]

and another diamine monomer, and 6FAP accounts for 15 mol % to 55 mol % of the diamine monomers. The another diamine monomer is

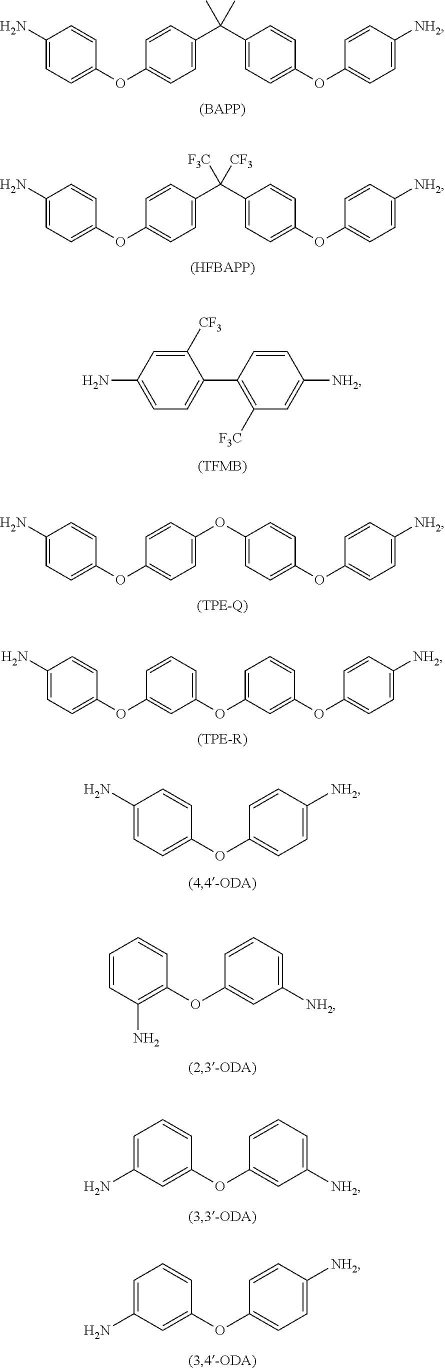

or a combination thereof.

One embodiment of the disclosure provides a multi-layered structure, including a first release film; and an electrochromic film disposed on the first release film, wherein the electrochromic film is formed by crosslinking the described electrochromic composition.

One embodiment of the disclosure provides an electrochromic device, including a transparent conductive layer; an electrochromic film disposed on the transparent conductive layer; and a conductive layer disposed on the electrochromic film, wherein the electrochromic film is disposed between the transparent conductive layer and the conductive layer, wherein the electrochromic film is formed by crosslinking the described electrochromic composition.

A detailed description is given in the following embodiments.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details.

One embodiment of the disclosure provides an electrochromic composition, including 100 parts by weight of polyimide, 0.0001 to 0.01 parts by weight (e.g., 0.0005 to 0.001 parts by weight) of crosslinking agent, 5 to 50 parts by weight (e.g., 8 to 18 parts by weight or 10 to 16 parts by weight) of electrochromic material, and 150 to 350 parts by weight (e.g., 200 to 260 parts by weight or 210 to 250 parts by weight) of solvent. If the amount of the crosslinking agent is too low, the polyimide will be insufficiently crosslinked, resulting in unstable formation. If the amount of cross-linking agent is excessive, the polyimide may be over-crosslinked, resulting in a brittle electrochromic film that adheres poorly to a transparent conductive layer. If the amount of the electrochromic material is too low, the electrochromic effect will be not obvious. If the amount of the electrochromic material is too high, it will occur precipitation. If the amount of the solvent is too low, the electrochromic composition will be too viscous to be coated. If the amount of the solvent is too high, the electrochromic composition will be too dilute to be coated as a film.

In some embodiments, the polyimide has an intrinsic viscosity of 10000 cps to 80000 cps at 190° C. The viscosity of the polyimide is positively related to the molecular weight of the polyimide. A higher viscosity means a larger molecular weight (e.g., a higher degree of polymerization). If the intrinsic viscosity of the polyimide is too low, it cannot ensure the precise thickness of the film. If the intrinsic viscosity of the polyimide is too high, the polyimide cannot be processed (e.g., cannot be coated).

In some embodiments, the electrochromic composition has a viscosity of 50000 cps to 120000 cps at room temperature. If the viscosity of the electrochromic composition is too low or too high, it will be difficult to coat the electrochromic composition as a film. The viscosity of the electrochromic composition can be adjusted by selecting the type or amount of the solvent, or adding auxiliary agent such as viscosity adjuster or levelling agent.

The polyimide is formed by reacting dianhydride monomers and diamine monomers. The dianhydride monomers are selected from at least two members of a group consisting of

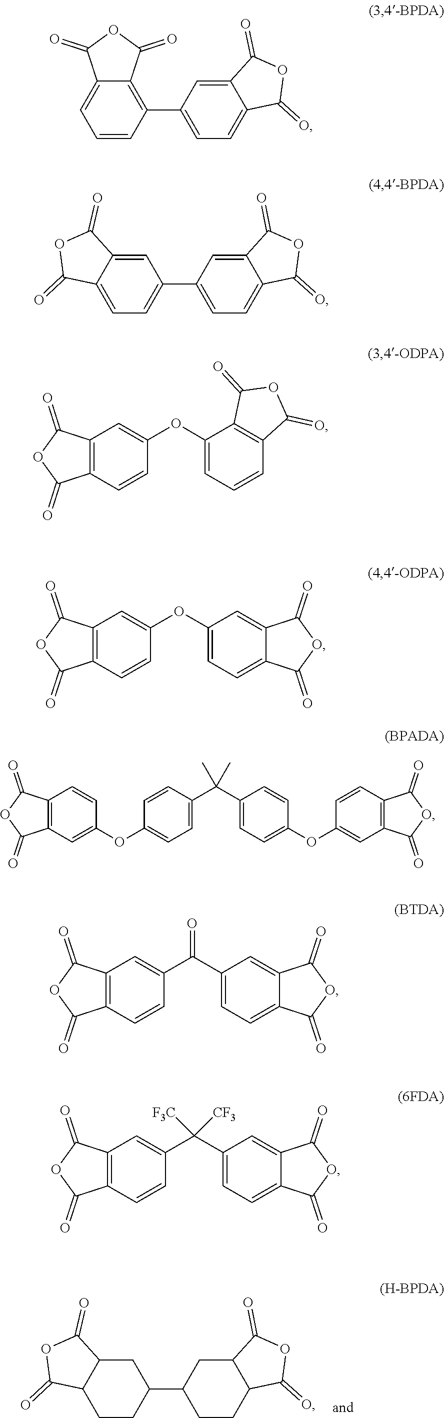

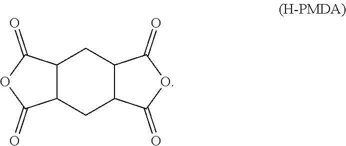 [SMILES: O=C1OC(=O)C2CC3C(=O)OC(=O)C3CC12]

In some embodiments, two or more dianhydride monomers are utilized to adjust the polymerization degree. In some embodiments, only one dianhydride monomer is utilized, and the polymerization may not undergo.

The diamine monomers are a combination of

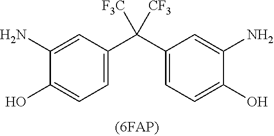 [SMILES: Nc1cc(C(c2ccc(O)c(N)c2)(C(F)(F)F)C(F)(F)F)ccc1O]

and another diamine monomer, and 6FAP accounts for 15 mol % to 55 mol % of the diamine monomers. If the amount of 6FPA is too low, the crosslinking of PI will be insufficient to form a stable electrochromic film. If the amount of 6FPA is too high, PI will be overly crosslinked, such that the electrochromic film will lack adhesion.

The another diamine monomer is

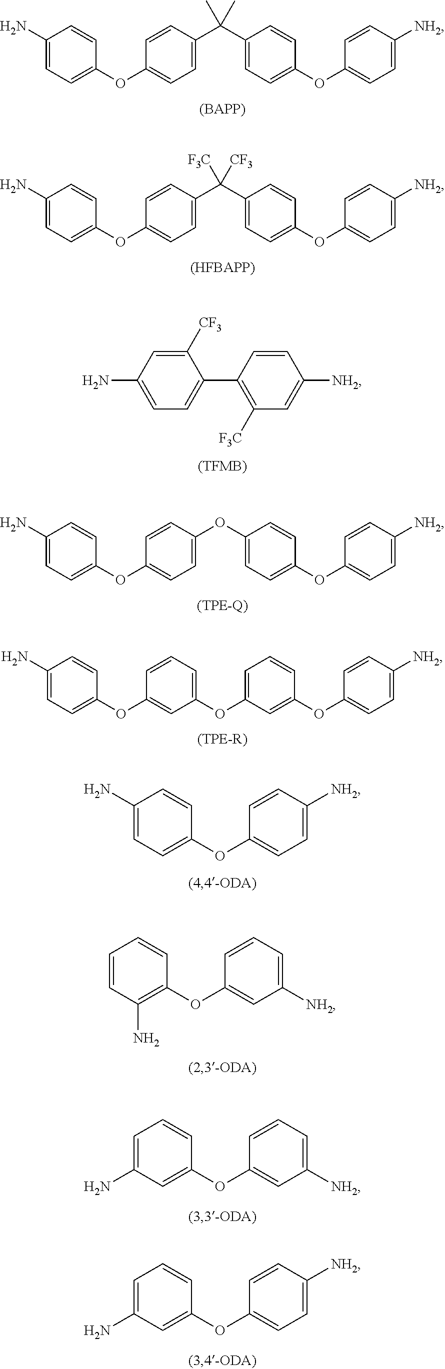

or a combination thereof.

In some embodiments, the crosslinking agent includes multi-isocyanate compound, such as aliphatic multi-isocyanate compound or aromatic multi-isocyanate compound. In some embodiments, the crosslinking agent includes toluene diisocyanate trimer, hexamethylene diisocyanate biuret, hexamethylene diisocyanate trimer, triphenylmethane-4,4′,4″-triisocyanate, or a combination thereof.

In some embodiments, the electrochromic material includes a cathode electrochromic material, an anode electrochromic material, or a combination thereof. In some embodiments, the cathode electrochromic material may include

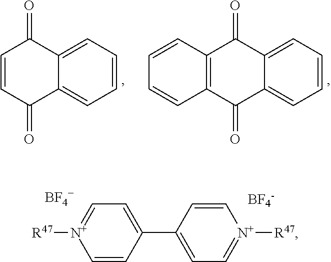

or a combination thereof, wherein each R⁴⁷ is independently hydrogen or C₁₋₁₀ alkyl group. According to embodiments of the disclosure, the C₁₋₁₀ alkyl group of the disclosure can be linear or branched alkyl group. In some embodiments, the anode electrochromic material may include

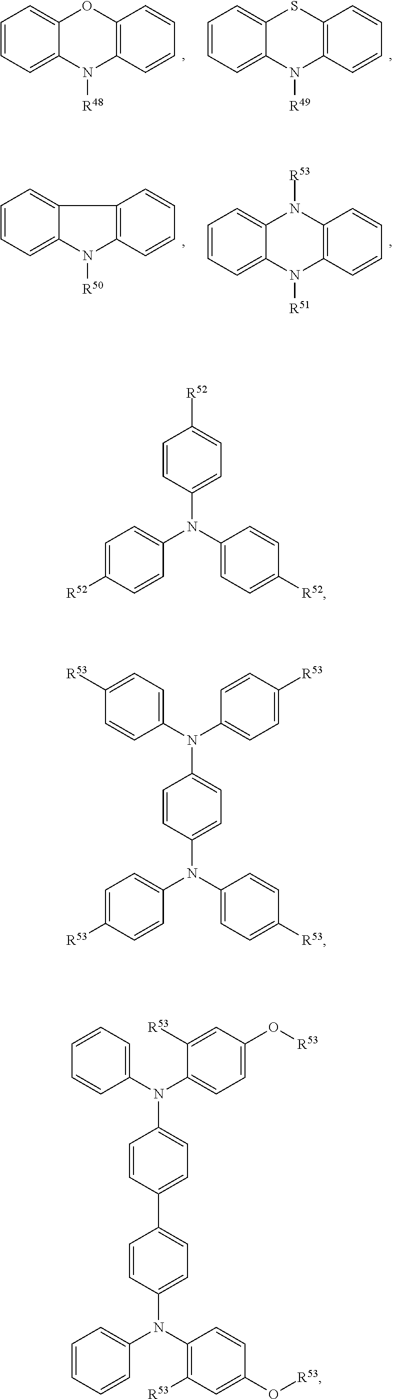

or a combination thereof, wherein each R⁴⁸, R⁴⁹, R⁵⁰, and R⁵¹ is independently hydrogen, C₁₋₁₀ alkyl group, or phenyl group. Each R⁵² and R⁵³ is independently hydrogen, amine, or C₁-3 alkoxy group. According to embodiments of the disclosure, C₁₋₃ alkoxy group can be linear or branched alkoxy group.

In some embodiments, the solvent includes ethylene carbonate, propyl acetate, diethyl carbonate, dimethyl carbonate, ethylmethyl carbonate, γ-butyrolactone, propylene carbonate, or a combination thereof.

One embodiment of the disclosure provides a multi-layered structure, including a first release film; and an electrochromic film disposed on the first release film, wherein the electrochromic film is formed by crosslinking the described electrochromic composition. For example, the electrochromic composition can be coated onto the first release film, and then heated to 50° C. to 60° C. to remove some solvent and crosslink PI to form the electrochromic film on the first release film. In some embodiments, the first release film can be polyolefin (PO)/PET release film, PE release film, oriented polypropylene (OPP) release film, PET fluorine-containing release film, or a combination thereof.

In some embodiments, the multi-layered structure further includes a second release film on the electrochromic film, wherein the electrochromic film is disposed between the first release film and the second release film, and the first release film has a release strength that is higher than that of the second release film. In some embodiments, the second release film can be polyolefin (PO)/PET release film, PE release film, oriented polypropylene (OPP) release film, PET fluorine-containing release film, or a combination thereof. For example, the second release film can be attached to the electrochromic film after forming the electrochromic film on the first release film. In some embodiments, the first release film has a release strength of 30 g to 200 g, and the second release film has a release strength of 1 g to 30 g. In some embodiments, the first release film has a release strength of 30 g to 100 g, and the second release film has a release strength of 1 g to 25 g.

In some embodiments, the multi-layered structure further includes a transparent conductive layer on the electrochromic film. For example, the transparent conductive layer can be attached to the electrochromic film after forming the electrochromic film on the first release film. The transparent conductive layer can be general transparent conductive oxide, such as indium tin oxide (ITO), fluorine doped tin oxide (FTO), antimony doped tin oxide (ATO), indium zinc oxide (IZO), aluminum zinc oxide (AZO), or zinc oxide (ZnO). It should be understood that one skilled in the art may pattern the transparent conductive layer to form the desired conductive lines. The transparent conductive layer can be formed on a flexible substrate such as a substrate of polyethylene terephthalate (PET) or the like.

In one embodiment of the disclosure, the electrochromic film has a thickness of 50 micrometers to 200 micrometers. If the electrochromic film is too thin, the electrochromic effect will be not obvious. If the electrochromic film is too thick, the device size and driving time will be increased.

One embodiment of the disclosure provides an electrochromic device, including a transparent conductive layer; an electrochromic film disposed on the transparent conductive layer; and a conductive layer disposed on the electrochromic film, wherein the electrochromic film is disposed between the transparent conductive layer and the conductive layer, wherein the electrochromic film is formed by crosslinking the described electrochromic composition. For example, after forming the electrochromic layer on the first release film and attaching the transparent conductive layer onto the electrochromic film, the first release film can be peeled off and the conductive layer can be attached to the electrochromic film for forming the electrochromic device. In one embodiment, after forming the multi-layered structure of first release film/electrochromic film/second release film, the second release film can be peeled off and the electrochromic film can be attached to the conductive layer, and the first release film can be then peeled off and the electrochromic film can be attached to the transparent conductive layer. In another embodiment, after forming the multi-layered structure of first release film/electrochromic film/second release film, the second release film can be peeled off and the electrochromic film can be attached to the transparent conductive layer, and the first release film can be then peeled off and the electrochromic film can be attached to the conductive layer. The electrochromic film will be disposed between the transparent conductive layer and the conductive layer regardless the type of the multi-layered structure or the order of the processes for forming the electrochromic device.

The conductive layer can be formed on a flexible substrate such as a substrate of polyethylene terephthalate (PET) or the like. It should be understood that the conductive layer can be patterned to form the desired conductive line. The conductive layer may include transparent conductive material or metal.

Below, exemplary embodiments will be described in detail so as to be easily realized by a person having ordinary knowledge in the art. The inventive concept may be embodied in various forms without being limited to the exemplary embodiments set forth herein.

### EXAMPLES

### Comparative Example 1

5 parts by weight of a cathode electrochromic material (having a chemical structure of

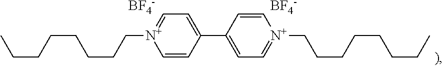 [SMILES: CCCCCCCC[n+]1ccc(-c2cc[n+](CCCCCCCC)cc2)cc1 ; "BF4-" ; "BF4-"]

14 parts by weight of an anode electrochromic material (Serial No.: 92-84-2, commercially available from ACROS), and 1 part by weight of tetrabutylammonium tetrafluoroborate were mixed in 200 parts by weight of γ-butyrolactone (GBL) to obtain GBL solution of electrochromic material. The total content of the cathode electrochromic material and the anode electrochromic material was 16 wt % (based on the weight of the GBL solution of electrochromic material).

44.34 g of BAPP (0.108 mole) and 4.4 g of 6FAP (0.012 mole) serving as diamine, 43.72 g of BPADA (0.084 mole) and 11.17 g of 3,4′-ODPA (0.036 mole) serving as dianhydride, 241.7 g g of GBL serving as solvent, 5.34 g of isoquinoline serving as polymerization catalyst were mixed, and then heated to 220° C. to react for 300 minutes to form polyimide (PI). In the above mixture, 6FPA accounted for 10 mol % of the diamine. The synthesized PI gel was pelletized (spun) and purified to obtain a solid component.

100 parts by weight of the PI solid component, 210 parts by weight of GBL, 0.0005 parts by weight of toluene diisocyanate trimer (N3200 commercially available from Covestro) serving as a crosslink agent, and 16 parts by weight of the electrochromic material were mixed to form an electrochromic composition. The electrochromic composition is placed in a 7 mL sample bottle, and baked at 50° C. for 60 minutes. The baking result was cooled at room temperature for 5 minutes, and the sample bottle was inverted for 10 seconds to measure the flow distance (0.7 cm) of the gel. In addition, the electrochromic gel was not stretchable.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 53 micrometers). The baking result was cooled at room temperature for 1 hour, but a wet continuous film could not be obtained (the film was discontinuous). The electrochromic film was attached to a transparent conductive layer ITO on PET, and the release film was then peeled off. However, some electrochromic film was remained on the release film.

The electrochromic composition was coated on a PO/PET release film (having release strength of 30 g), and then baked at 50° C. for 12 minutes to remove some solvent and crosslink PI to form an electrochromic film (having a thickness of 96 micrometers). The baking result was cooled at room temperature for 1 hour, but a wet continuous film could not be obtained (the film was discontinuous). The electrochromic film was attached to a transparent conductive layer ITO on PET, and the release film was then peeled off. However, some electrochromic film was remained on the release film.

The electrochromic composition was coated on a PO/PET release film (having release strength of 30 g), and then baked at 50° C. for 12 minutes to remove some solvent and crosslink PI to form an electrochromic film (having a thickness of 196 micrometers). The baking result was cooled at room temperature for 1 hour, but a wet continuous film could not be obtained (the film was discontinuous). The electrochromic film was attached to a transparent conductive layer ITO on PET, and the release film was then peeled off. However, some electrochromic film was remained on the release film.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 53 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by a film thickness gauge to calculate its height change ratio (>30%). The multi-layered structure was pressed by thumb, and the multi-layered structure was analyzed by the film thickness gauge (the dent could not be recovered).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 96 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (>30%). The multi-layered structure was pressed by thumb, and the multi-layered structure was analyzed by the film thickness gauge (the dent could not be recovered).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 196 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge (Japan Mitutoyo digital micrometer 543 series) to calculate its height change ratio (>30%). The multi-layered structure was pressed by thumb (equal to 200 g weight pressing), and the multi-layered structure was analyzed by the film thickness gauge (the dent could not be recovered).

As shown above, when the content of 6FPA in the diamine for forming PI was too low, the crosslinking degree of PI would be insufficient to form a stable electrochromic film.

### Example 1

39.41 g of BAPP (0.096 mole) and 8.79 g of 6FAP (0.024 mole) serving as diamine, 43.72 g of BPADA (0.084 mole) and 11.17 g of 3,4′-ODPA (0.036 mole) serving as dianhydride, 240.54 g of GBL serving as solvent, and 5.31 g of isoquinoline serving as polymerization catalyst were mixed, and then heated to 220° C. to react for 300 minutes to form polyimide (PI). In the above mixture, 6FPA accounted for 20 mol % of the diamine. The synthesized PI gel was pelletized (spun) and purified to obtain a solid component.

100 parts by weight of the PI solid component, 210 parts by weight of GBL, 0.0005 parts by weight of toluene diisocyanate trimer (N3200 commercially available from Covestro) serving as a crosslink agent, and 16 parts by weight of the electrochromic material were mixed to form an electrochromic composition. The electrochromic composition is placed in a 7 mL sample bottle, and baked at 50° C. for 60 minutes. The baking result was cooled at room temperature for 5 minutes, and the sample bottle was inverted for 10 seconds to measure the flow distance (0.2 cm) of the gel. In addition, the electrochromic gel was wet and stretchable.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 56 micrometers). The baking result was cooled at room temperature for 1 hour to form a wet continuous film. The electrochromic film was attached to a transparent conductive layer ITO on PET, and the release film was then peeled off. The electrochromic film could be transferred to the transparent conductive layer ITO well. Another transparent conductive layer ITO on PET was attached to the electrochromic film, and each of the two transparent conductive layers had an area of 3 cm*5 cm. The device was driven by a driving voltage of 1.5 V. The device had a light transmittance of 84.1% to the light having a wavelength of 550 nm before being driven, and had a light transmittance of 22.9% to the light having a wavelength of 550 nm after being driven.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 125 micrometers). The baking result was cooled at room temperature for 1 hour to form a wet continuous film. The electrochromic film was attached to a transparent conductive layer ITO on PET, and the release film was then peeled off. The electrochromic film could be transferred to the transparent conductive layer ITO well.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 186 micrometers). The baking result was cooled at room temperature for 1 hour to form a wet continuous film. The electrochromic film was attached to a transparent conductive layer ITO on PET, and the release film was then peeled off. The electrochromic film could be transferred to the transparent conductive layer ITO well. Another transparent conductive layer ITO on PET was attached to the electrochromic film, and each of the two transparent conductive layers had an area of 3 cm*5 cm. The device was driven by a driving voltage of 1.5 V. The device had a light transmittance of 80.9% to the light having a wavelength of 550 nm before being driven, and had a light transmittance of 2.6% to the light having a wavelength of 550 nm after being driven.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 56 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (2.7%). The multi-layered structure was pressed by thumb, and the multi-layered structure was analyzed by the film thickness gauge (no dent was occurred).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 125 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (4.25%). The multi-layered structure was pressed by thumb, and the multi-layered structure was analyzed by the film thickness gauge (no dent was occurred).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 186 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (7.4%). The multi-layered structure was pressed by thumb, and the multi-layered structure was analyzed by the film thickness gauge (slight dent could be recovered).

### Example 2

29.56 g of BAPP (0.072 mole) and 17.58 g of 6FAP (0.048 mole) serving as diamine, 43.72 g of BPADA (0.084 mole) and 11.17 g of 3,4′-ODPA (0.036 mole) serving as dianhydride, 238.06 g of GBL serving as solvent, and 5.26 g of isoquinoline serving as polymerization catalyst were mixed, and then heated to 220° C. to react for 300 minutes to form polyimide (PI). In the above mixture, 6FPA accounted for 40 mol % of the diamine. The synthesized PI gel was pelletized (spun) and purified to obtain a solid component.

100 parts by weight of the PI solid component, 210 parts by weight of GBL, 0.0005 parts by weight of toluene diisocyanate trimer (N3200 commercially available from Covestro) serving as a crosslink agent, and 16 parts by weight of the electrochromic material were mixed to form an electrochromic composition. The electrochromic composition is placed in a 7 mL sample bottle, and baked at 50° C. for 60 minutes. The baking result was cooled at room temperature for 5 minutes, and the sample bottle was inverted for 10 seconds to measure the flow distance (0 cm) of the gel. In addition, the electrochromic gel was wet and stretchable.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 43 micrometers). The baking result was cooled at room temperature for 1 hour to form a wet continuous film. The electrochromic film was attached to a transparent conductive layer ITO on PET, and the release film was then peeled off. The electrochromic film could be transferred to the transparent conductive layer ITO well. Another transparent conductive layer ITO on PET was attached to the electrochromic film, and each of the two transparent conductive layers had an area of 3 cm*5 cm. The device was driven by a driving voltage of 1.5 V. The device had a light transmittance of 85.6% to the light having a wavelength of 550 nm before being driven, and had a light transmittance of 24.4% to the light having a wavelength of 550 nm after being driven.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 162 micrometers). The baking result was cooled at room temperature for 1 hour to form a wet continuous film. The electrochromic film was attached to a transparent conductive layer ITO on PET, and the release film was then peeled off. The electrochromic film could be transferred to the transparent conductive layer ITO well. Another transparent conductive layer ITO on PET was attached to the electrochromic film, and each of the two transparent conductive layers had an area of 3 cm*5 cm. The device was driven by a driving voltage of 1.5 V. The device had a light transmittance of 81.2% to the light having a wavelength of 550 nm before being driven, and had a light transmittance of 4.2% to the light having a wavelength of 550 nm after being driven.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 43 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (2.4%). The multi-layered structure was pressed by thumb, and the multi-layered structure was analyzed by the film thickness gauge (no dent was occurred).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 98 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (3.2%). The multi-layered structure was pressed by thumb, and the multi-layered structure was analyzed by the film thickness gauge (no dent was occurred).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 162 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (6.2%). The multi-layered structure was pressed by thumb, and the multi-layered structure was analyzed by the film thickness gauge (slight dent could be recovered).

### Example 3

22.17 g of BAPP (0.054 mole) and 24.17 g of 6FAP (0.066 mole) serving as diamine, 43.72 g of BPADA (0.084 mole) and 11.17 g of 3,4′-ODPA (0.036 mole) serving as dianhydride, 236.2 g of GBL serving as solvent, and 5.22 g of isoquinoline serving as polymerization catalyst were mixed, and then heated to 220° C. to react for 300 minutes to form polyimide (PI). In the above mixture, 6FPA accounted for 55 mol % of the diamine. The synthesized PI gel was pelletized (spun) and purified to obtain a solid component.

100 parts by weight of the PI solid component, 210 parts by weight of GBL, 0.0005 parts by weight of toluene diisocyanate trimer (N3200 commercially available from Covestro) serving as a crosslink agent, and 16 parts by weight of the electrochromic material were mixed to form an electrochromic composition. The electrochromic composition is placed in a 7 mL sample bottle, and baked at 50° C. for 60 minutes. The baking result was cooled at room temperature for 5 minutes, and the sample bottle was inverted for 10 seconds to measure the flow distance (0 cm) of the gel. In addition, the electrochromic gel was wet and stretchable.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 43 micrometers). The baking result was cooled at room temperature for 1 hour to form a wet continuous film. The electrochromic film was attached to a transparent conductive layer ITO on PET, and the release film was then peeled off. The electrochromic film could be transferred to the transparent conductive layer ITO well. Another transparent conductive layer ITO on PET was attached to the electrochromic film, and each of the two transparent conductive layers had an area of 3 cm*5 cm. The device was driven by a driving voltage of 1.5 V. The device had a light transmittance of 85.6% to the light having a wavelength of 550 nm before being driven, and had a light transmittance of 24.4% to the light having a wavelength of 550 nm after being driven.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 162 micrometers). The baking result was cooled at room temperature for 1 hour to form a wet continuous film. The electrochromic film was attached to a transparent conductive layer ITO on PET, and the release film was then peeled off. The electrochromic film could be transferred to the transparent conductive layer ITO well. Another transparent conductive layer ITO on PET was attached to the electrochromic film, and each of the two transparent conductive layers had an area of 3 cm*5 cm. The device was driven by a driving voltage of 1.5 V. The device had a light transmittance of 81.2% to the light having a wavelength of 550 nm before being driven, and had a light transmittance of 4.2% to the light having a wavelength of 550 nm after being driven.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 43 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (2.4%). The multi-layered structure was pressed by thumb, and the multi-layered structure was analyzed by the film thickness gauge (no dent was occurred).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 109 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (3.7%). The multi-layered structure was pressed by thumb, and the multi-layered structure was analyzed by the film thickness gauge (no dent was occurred).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 162 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (6.1%). The multi-layered structure was pressed by thumb, and the multi-layered structure was analyzed by the film thickness gauge (slight dent could be recovered).

### Comparative Example 2

14.78 g of BAPP (0.036 mole) and 30.77 g of 6FAP (0.084 mole) serving as diamine, 43.72 g of BPADA (0.084 mole) and 11.17 g of 3,4′-ODPA (0.036 mole) serving as dianhydride, 234.34 g of GBL serving as solvent, and 5.18 g of isoquinoline serving as polymerization catalyst were mixed, and then heated to 220° C. to react for 300 minutes to form polyimide (PI). In the above mixture, 6FPA accounted for 70 mol % of the diamine. The synthesized PI gel was pelletized (spun) and purified to obtain a solid component.

100 parts by weight of the PI solid component, 210 parts by weight of GBL, 0.0005 parts by weight of toluene diisocyanate trimer (N3200 commercially available from Covestro) serving as a crosslink agent, and 16 parts by weight of the electrochromic material were mixed to form an electrochromic composition. The electrochromic composition is placed in a 7 mL sample bottle, and baked at 50° C. for 60 minutes. The baking result was cooled at room temperature for 5 minutes, and the sample bottle was inverted for 10 seconds to measure the flow distance (0 cm) of the gel. In addition, the electrochromic gel was brittle and not stretchable.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 62 micrometers). The baking result was cooled at room temperature for 1 hour to form a brittle continuous film. The electrochromic film was attached to a transparent conductive layer ITO on PET, and the release film was then peeled off. The electrochromic film was free of adhesion and could not be transferred to the transparent conductive layer ITO.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 112 micrometers). The baking result was cooled at room temperature for 1 hour to form a brittle continuous film. The electrochromic film was attached to a transparent conductive layer ITO on PET, and the release film was then peeled off. The electrochromic film was free of adhesion and could not be transferred to the transparent conductive layer ITO.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 188 micrometers). The baking result was cooled at room temperature for 1 hour to form a brittle continuous film. The electrochromic film was attached to a transparent conductive layer ITO on PET, and the release film was then peeled off. The electrochromic film was free of adhesion and could not be transferred to the transparent conductive layer ITO.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 62 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (0%). The multi-layered structure was pressed by thumb, and the multi-layered structure was analyzed by the film thickness gauge (no dent was occurred).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 112 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (0%). The multi-layered structure was pressed by thumb, and the multi-layered structure was analyzed by the film thickness gauge (no dent was occurred).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 188 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (0%). The multi-layered structure was pressed by thumb, and the multi-layered structure was analyzed by the film thickness gauge (no dent was occurred).

As shown above, when the content of 6FPA in the diamine for PI was too high, the PI would be crosslinked too much, such that the electrochromic film would be free of adhesion.

### Example 4

49.88 g of BAPP (0.122 mole) and 10.44 g of 6FAP (0.029 mole) serving as diamine, 22.07 g of 3,4′-BPDA (0.075 mole) and 16.81 g of H-PMDA (0.075 mole) serving as dianhydride, 231.45 g of GBL serving as solvent, and 5.11 g of isoquinoline serving as polymerization catalyst were mixed, and then heated to 220° C. to react for 300 minutes to form polyimide (PI). In the above mixture, 6FPA accounted for 19 mol % of the diamine. The synthesized PI gel was pelletized (spun) and purified to obtain a solid component.

100 parts by weight of the PI solid component, 210 parts by weight of GBL, 0.0005 parts by weight of toluene diisocyanate trimer (N3200 commercially available from Covestro) serving as a crosslink agent, and 16 parts by weight of the electrochromic material were mixed to form an electrochromic composition. The electrochromic composition is placed in a 7 mL sample bottle, and baked at 50° C. for 60 minutes. The baking result was cooled at room temperature for 5 minutes, and the sample bottle was inverted for 10 seconds to measure the flow distance (0 cm) of the gel. In addition, the electrochromic gel was wet and stretchable.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 51 micrometers). The baking result was cooled at room temperature for 1 hour to form a wet continuous film. The electrochromic film was attached to a transparent conductive layer ITO on PET, and the release film was then peeled off. The electrochromic film could be transferred to the transparent conductive layer ITO well. Another transparent conductive layer ITO on PET was attached to the electrochromic film, and each of the two transparent conductive layers had an area of 3 cm*5 cm. The device was driven by a driving voltage of 1.5 V. The device had a light transmittance of 84.9% to the light having a wavelength of 550 nm before being driven, and had a light transmittance of 21.53% to the light having a wavelength of 550 nm after being driven.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 109 micrometers). The baking result was cooled at room temperature for 1 hour to form a wet continuous film. The electrochromic film was attached to a transparent conductive layer ITO on PET, and the release film was then peeled off. The electrochromic film could be transferred to the transparent conductive layer ITO well.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 192 micrometers). The baking result was cooled at room temperature for 1 hour to form a wet continuous film. The electrochromic film was attached to a transparent conductive layer ITO on PET, and the release film was then peeled off. The electrochromic film could be transferred to the transparent conductive layer ITO well. Another transparent conductive layer ITO on PET was attached to the electrochromic film, and each of the two transparent conductive layers had an area of 3 cm*5 cm. The device was driven by a driving voltage of 1.5 V. The device had a light transmittance of 80.4% to the light having a wavelength of 550 nm before being driven, and had a light transmittance of 0.8% to the light having a wavelength of 550 nm after being driven.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 51 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (2.9%). The multi-layered structure was pressed by thumb, and the multi-layered structure was analyzed by the film thickness gauge (no dent was occurred).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 109 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (3.7%). The multi-layered structure was pressed by thumb, and the multi-layered structure was analyzed by the film thickness gauge (no dent was occurred).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 192 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (5.8%). The multi-layered structure was pressed by thumb, and the multi-layered structure was analyzed by the film thickness gauge (slight dent could be recovered).

### Comparative Example 3

11.49 g of BAPP (0.028 mole) and 34.44 g of 4,4′-ODA (0.172 mole) serving as diamine, 49.64 g of B1317 (0.2 mole, Bicyclo[2.2.2]oct-7-ene-2,3,5,6-tetracarboxylic Dianhydride commercially available from Société Suisse des Explosifs (SSE) group) serving as dianhydride, 223.0 g of GBL serving as solvent, and 4.93 g of isoquinoline serving as polymerization catalyst were mixed, and then heated to 220° C. to react for 300 minutes to form polyimide (PI). In the above mixture, 6FPA accounted for 0 mol % of the diamine. The synthesized PI gel was pelletized (spun) and purified to obtain a solid component. B1317 had a chemical structure of

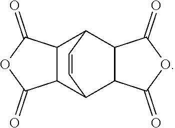 [SMILES: O=C1OC(=O)C2C3C=CC(C12)C1C(=O)OC(=O)C31]

100 parts by weight of the PI solid component, 210 parts by weight of GBL, 0.0005 parts by weight of toluene diisocyanate trimer (N3200 commercially available from Covestro) serving as a crosslink agent, and 16 parts by weight of the electrochromic material were mixed to form an electrochromic composition. The electrochromic composition is placed in a 7 mL sample bottle, and baked at 50° C. for 60 minutes. The baking result was cooled at room temperature for 5 minutes, and the sample bottle was inverted for 10 seconds to measure the flow distance (0.5 cm) of the gel. In addition, the electrochromic gel was not stretchable.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 58 micrometers). The baking result was cooled at room temperature for 1 hour, but it could not crosslink to form a wet continuous film (e.g., the film was discontinuous). The electrochromic film was attached to a transparent conductive layer ITO on PET, and the release film was then peeled off. However, the electrochromic film flowed to the outside of ITO.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 108 micrometers). The baking result was cooled at room temperature for 1 hour, but it could not crosslink to form a wet continuous film (e.g., the film was discontinuous). The electrochromic film was attached to a transparent conductive layer ITO on PET, and the release film was then peeled off. However, the electrochromic film flowed to the outside of ITO.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 169 micrometers). The baking result was cooled at room temperature for 1 hour, but it could not crosslink to form a wet continuous film (e.g., the film was discontinuous). The electrochromic film was attached to a transparent conductive layer ITO on PET, and the release film was then peeled off. However, the electrochromic film flowed to the outside of ITO.

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 58 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (>30%). The multi-layered structure was pressed by thumb, and the multi-layered structure was analyzed by the film thickness gauge (dent could not be recovered).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 108 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (>30%). The multi-layered structure was pressed by thumb, and the multi-layered structure was analyzed by the film thickness gauge (dent could not be recovered).

The electrochromic composition was coated on a release film (PO/PET release film having release strength of 30 g, commercially available from Nanya functional film), and then baked at 50° C. for 12 minutes to remove some solvent and crosslink PI to form an electrochromic film (having a thickness of 169 micrometers). The baking result was cooled at room temperature for 1 hour, and another release film (PO/PET release film having release strength of 10 g, commercially available from Nanya functional film) was used to cover the electrochromic film to form a multi-layered structure. 2 g of force was applied to the multi-layered structure for 30 seconds, and the heights of the multi-layered structure before and after applying the force were measured by the film thickness gauge to calculate its height change ratio (>30%). The multi-layered structure was pressed by thumb, and the multi-layered structure was analyzed by the film thickness gauge (dent could not be recovered).

As shown above, when PI was free of 6FPA, it could not be proper to form the electrochromic film (could not form a stable structure due to it was not crosslinked).

### Comparative Example 4

19.16 g of IPDA (0.113 mole) and 13.74 g of 6FPA (0.038 mole) serving as diamine, 54.65 g of BPADA (0.105 mole) and 13.96 g of 3,4′-ODPA (0.045 mole) serving as dianhydride, 236.84 g of GBL serving as solvent, and 5.23 g of isoquinoline serving as polymerization catalyst were mixed, and then heated to 220° C. to react for 300 minutes to form polyimide (PI). However, the above polymerization could not undergo, i.e., IPDA was not suitable to combine with 6FPA to form PI. IPDA had a chemical structure of

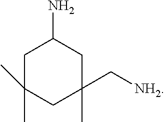

### Comparative Example 5

14.42 g of HTDA (0.113 mole) and 13.74 g of 6FPA (0.038 mole) serving as diamine, 54.65 g of BPADA (0.105 mole) and 13.96 g of 3,4′-ODPA (0.045 mole) serving as dianhydride, 225.80 g of GBL serving as solvent, and 4.99 g of isoquinoline serving as polymerization catalyst were mixed, and then heated to 220° C. to react for 300 minutes to form polyimide (PI). However, the above polymerization could not undergo, i.e., HTDA was not suitable to combine with 6FPA to form PI. HTDA had a chemical structure of

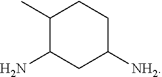

### Comparative Example 6

36.95 g of BAPP (0.090 mole) and 10.99 g of 6FPA (0.030 mole) serving as diamine, 31.23 g of BPADA (0.060 mole) and 11.77 g of CBDA (0.060 mole) serving as dianhydride, 212.17 g of GBL serving as solvent, and 4.69 g of isoquinoline serving as polymerization catalyst were mixed, and then heated to 220° C. to react for 300 minutes to form polyimide (PI). However, the above polymerization could not undergo, i.e., CBDA was not suitable to combine with 6FPA to form PI. CBDA had a chemical structure of

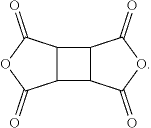 [SMILES: O=C1OC(=O)C2C1C1C(=O)OC(=O)C21]

### Comparative Example 7

36.95 g of BAPP (0.090 mole) and 10.99 g of 6FPA (0.030 mole) serving as diamine, 43.72 g of BPADA (0.084 mole) and 7.06 g of CBDA (0.036 mole) serving as dianhydride, 230.33 g of GBL serving as solvent, and 5.09 g of isoquinoline serving as polymerization catalyst were mixed, and then heated to 220° C. to react for 300 minutes to form polyimide (PI). However, the above polymerization could not undergo, i.e., CBDA was not suitable to combine with 6FPA to form PI.

It will be apparent to those skilled in the art that various modifications and variations can be made to the disclosed methods and materials. It is intended that the specification and examples be considered as exemplary only, with the true scope of the disclosure being indicated by the following claims and their equivalents.

What is claimed is:

1. An electrochromic composition, comprising:
100 parts by weight of polyimide,
0.0001 to 0.01 parts by weight of crosslinking agent,
5 to 50 parts by weight of electrochromic material, and
150 to 350 parts by weight of solvent,
wherein the polyimide is formed by reacting dianhydride monomers and diamine monomers,
wherein the dianhydride monomers are selected from at least two members of a group consisting of 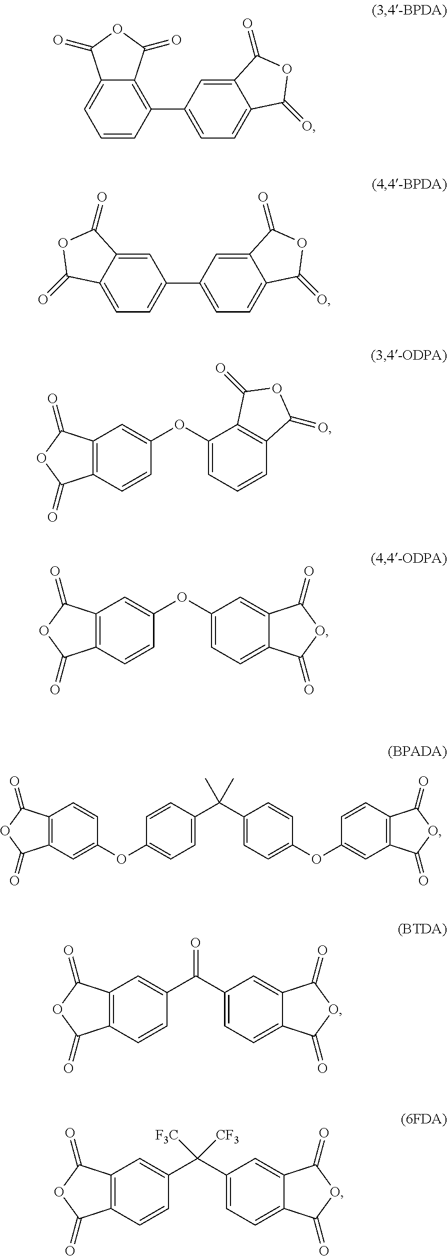 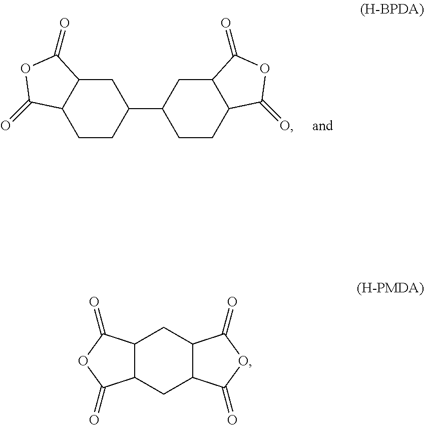 [SMILES: O=C1OC(=O)C2CC(C3CCC4C(=O)OC(=O)C4C3)CCC12 ; O=C1OC(=O)C2CC3C(=O)OC(=O)C3CC12]
wherein the diamine monomers are a combination of 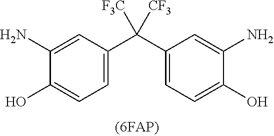 [SMILES: Nc1cc(C(c2ccc(O)c(N)c2)(C(F)(F)F)C(F)(F)F)ccc1O]
and another diamine monomer, and 6FAP accounts for 15 mol % to 55 mol % of the diamine monomers, and the another diamine monomer is 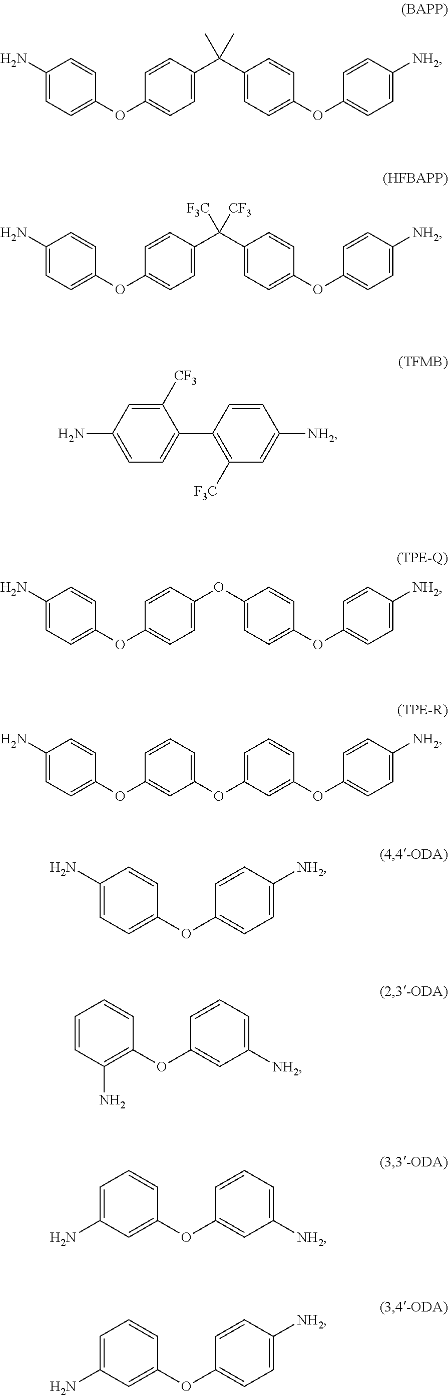
or a combination thereof.

2. The electrochromic composition as claimed in claim 1, wherein the crosslinking agent comprises multi-isocyanate compound.

3. The electrochromic composition as claimed in claim 1, wherein the electrochromic material comprises a cathode electrochromic material, an anode electrochromic material, or a combination thereof.

4. The electrochromic composition as claimed in claim 1, wherein the solvent comprises ethylene carbonate, propyl acetate, diethyl carbonate, dimethyl carbonate, ethylmethyl carbonate, γ-butyrolactone, propylene carbonate, or a combination thereof.

5. A multi-layered structure, comprising:
a first release film; and
an electrochromic film disposed on the first release film,
wherein the electrochromic film is formed by crosslinking the electrochromic composition as claimed in claim 1.

6. The multi-layered structure as claimed in claim 5, further comprising a second release film disposed on the electrochromic film, wherein the electrochromic film is disposed between the first release film and the second release film, and a release strength of the first release film is higher than a release strength of the second release film.

7. The multi-layered structure as claimed in claim 5, further comprising a transparent conductive layer disposed on the electrochromic film.

8. The multi-layered structure as claimed in claim 5, wherein the electrochromic film has a thickness of 50 micrometers to 200 micrometers.

9. An electrochromic device, comprising:
a transparent conductive layer;
an electrochromic film disposed on the transparent conductive layer; and
a conductive layer disposed on the electrochromic film,
wherein the electrochromic film is disposed between the transparent conductive layer and the conductive layer,
wherein the electrochromic film is formed by crosslinking the electrochromic composition as claimed in claim 1.

10. The electrochromic device as claimed in claim 9, wherein the conductive layer comprises transparent conductive material or metal.
